(19) United States
(12) Patent Application Publication
(10) Pub. No.: US 2022/0336528 A1
(43) Pub. Date: Oct. 20, 2022

(54) LIGHTING SYSTEM

(71) Applicant: LightnTec GmbH, Karlsruhe (DE)

(72) Inventor: Florian Kall, Karlsruhe (DE)

(73) Assignee: LightnTec GmbH, Karlsruhe (DE)

(21) Appl. No.: 17/806,918

(22) Filed: Jun. 14, 2022

Related U.S. Application Data
(63) Continuation of application No. PCT/EP2021/067624, filed on Jun. 28, 2021.

(30) Foreign Application Priority Data
Jun. 30, 2020 (DE) 10 2020 208 112.3

(51) Int. Cl. H01L 27/15; G09F 9/33; F21V 8/00; G02B 3/00; G09F 9/302; G02B 5/20

(52) U.S. Cl. CPC H01L 27/156; G09F 9/33; G02B 6/0068; G02B 3/0056; G09F 9/3026; G02B 5/20

(57) ABSTRACT

A lighting system for displaying animations, in particular for advertising purposes, has a plurality of light sources, preferably light-emitting diodes. The light sources are held on a base structure. A color layer is arranged on the base structure. The base structure includes a recess for each of the light sources. A controller is configured for actuating the light sources in a synchronized manner in a chronological sequence in order to reproduce the animations.

### CROSS-REFERENCE TO RELATED APPLICATIONS

This continuation application claims priority to PCT/EP2021/067624 filed on Jun. 28, 2021 which has published as WO 2022/002817 A1 and also the German application number 10 2020 208 112.3 filed on Jun. 30, 2020, the entire contents of which are fully incorporated herein with these references.

### DESCRIPTION

### Field of the Invention

The invention relates to a lighting system comprising a plurality of light sources and a base structure on which the light sources are held.

### Background of the Invention

Such lighting systems are known in principle from the prior art.

Screens or similar display devices typically comprise a visible surface and many light sources, the visible surface giving a black color impression when the light sources are switched off. When the light sources are switched on, a pixel associated with the relevant light source appears in the color of the relevant light source or as a color overlay of the colors of the light sources associated with the pixel.

In other lighting systems, a diffuser can be arranged in front of a plurality of light sources. The light emitted by the individual light sources can be scattered by the diffuser for a uniform lighting impression. The diffuser can in this case prevent the individual light sources from being perceived separately.

Furthermore, planar advertising elements are known, for example in the form of panels or columns, which can be colored. The advertising elements can be designed in the form of characters or symbols or can comprise characters or symbols due to a color design which is different in some regions. Such advertising elements can be illuminated from their viewing side or backlit from their rear side.

DE 20 2009 002 330 U1 discloses a garment in the form of outerwear or trousers. The garment contains a flexible ribbon cable connected to light-emitting diodes, a colored or transparent plastics layer under the ribbon cable, and a colored or reflective cover layer on the ribbon cable. The cover layer comprises a plurality of holes through which the light-emitting diodes connected to the ribbon cable are guided. The garment also comprises a receiving space for a battery box, on which a power switch is provided that can be operated from the outside.

WO 2019/162268 A1 discloses a shaped part having an opaque decorative layer, with at least two symbols being provided on the front side. The decorative layer comprises one or more (second) light channels. The decorative layer can be a wood veneer. The shaped part also has a transparent or translucent carrier. Furthermore, the shaped part has one or more (second) functional elements, each (second) functional element comprising a (second) light element, and a (second) functional layer, the (second) functional layer being provided on the rear side of the decorative layer. The (second) functional elements are provided in or on the second functional layer and on and/or at least in portions in the second light channels. Furthermore, the decorative layer comprises one or more (first) light channels. The shaped part also has one or more first functional elements, each first functional element comprising a first light element. The second functional elements cover the second light channels of the decorative layer in such a way that the second light channels are isolated from light from the first light elements. The first and second light channels are provided for displaying a first and second symbol, respectively, on the front side.

### SUMMARY OF THE INVENTION

### Object of the Invention

An object of the invention is that of providing a lighting system which improves the perceptibility of advertising elements.

### DESCRIPTION OF THE INVENTION

This object is achieved according to the invention by a lighting system according to claim 1. Advantageous embodiments are specified in the dependent claims and the description.

According to the invention, a lighting system is provided. The lighting system is suitable for displaying animations. In this case, animations are understood to mean, in particular, continuous color patterns or light patterns which change over time. The lighting system can be used in particular for advertising purposes. For this purpose, the lighting system preferably reproduces animations intermittently. It is understood that the lighting system can also reproduce stationary patterns, such as images.

The lighting system comprises a plurality of light sources. The light sources can be actuated in a suitable manner in order to reproduce or play the animations; in other words, animated representations can be reproduced by corresponding actuation of the light sources. The light sources are preferably designed as light-emitting diodes. The lighting system also comprises a base structure. The light sources are held on the base structure. Lines for supplying power to the light sources can be integrated into the base structure. The light sources can be punctiform, it being possible for an extension of the light sources to be at most 5 mm, preferably at most 3 mm, in each case.

According to the invention, the lighting system comprises a color layer. The color layer is arranged on the base structure. The color layer comprises a recess for each of the light sources. The recesses are in principle transparent and colorless. A surface proportion of the recesses is at most 30%, preferably at most 20%, particularly preferably at most 10%. A light source is typically assigned with exactly one recess.

The color layer can improve the perceptibility of the lighting system or of an advertising element comprising the lighting system when the light sources are switched off. When the light sources are switched off, the lighting system conveys a color impression determined by the color layer. In this case, the light sources arranged at the recesses remain behind the colored regions, i.e. the non-recessed regions, of the color layer in terms of optical perception. When the light sources are switched off, the lighting system can act like wallpaper, for example white or colored wallpaper, due to the color layer.

The lighting system can be illuminated by switching on at least some of the light sources. In this way, the perceptibility of the lighting system or of an advertising element comprising the lighting system can be improved, in particular in the dark. The perception of the lighting system can be further improved by reproducing light representations by means of said lighting system. In particular, playing animations allows additional information to be reproduced, for example in the form of images or film segments or texts. Because the color layer comprises a recess for each of the light sources, the light output of the individual light sources can be better distinguished by an observer. In particular, the recesses can make it possible to perceive smaller differences in brightness and greater image sharpness than is possible in the case of lighting systems having a diffuser that are known from the prior art.

A distance between adjacent light sources can be at least 2 mm, preferably at least 3 mm. This can improve the color effect of the color layer. The distance between adjacent light sources can be at most 10 cm, preferably at most 5 cm. This improves the resolution of the patterns or animations which can be displayed by the light sources.

The color layer is not continuously black. The color layer can comprise achromatic colors, such as black, white, gray or silver, at least in some regions. If the color layer is black in some regions, the black surface proportion is in principle at most 20%, preferably at most 10%, particularly preferably at most 5%. The color layer can comprise chromatic, in particular pure, colors at least in some regions, preferably completely (with the exception of the recesses). The color layer can be single-colored or multicolored.

The color layer can show a logo or a symbol as a whole, i.e. with the total area thereof. A coloring of the color layer can correspond to the corporate colors (the corporate identity) of a company to be advertised using the lighting system.

The color layer may be applied directly to the base structure. This allows the lighting system to be produced in a particularly favorable manner. The color layer can, for example, be painted or printed onto the base structure.

Alternatively, the color layer can be applied to a carrier structure. The base structure and the carrier structure are in principle designed as components which are separate from one another. Due to the separate carrier structure, special color effects of the color layer can be achieved. Furthermore, as a result of the separate carrier structure for the color layer, it can be particularly effectively achieved that, when the light sources are switched off, only the color layer is perceived, while the light sources remain behind the color layer on the carrier structure in terms of the optical impression. The carrier structure can be made of polystyrene. Alternatively, the carrier structure can be a sheet metal plate. The color layer can be printed or painted onto the carrier structure. Alternatively, the carrier structure can be colored throughout.

The carrier structure and the base structure can be glued directly to one another. This simplifies the production of the lighting system. Furthermore, as a result, a radiation angle of the individual light sources can be increased by the respective recesses.

Alternatively, the carrier structure can be arranged at a distance from the base structure. This contributes to concealing the light sources when they are switched off. Furthermore, a directional characteristic for the light emitted by the light sources through the relevant recess can be achieved in this way. A distance between the carrier structure and the base structure is at most 10 mm, preferably at most 7 mm, particularly preferably at most 5 mm. The distance between the carrier structure and the base structure is typically at least 1 mm, preferably at least 2 mm. The base structure and the carrier structure can be glued to one another via spacer elements.

The recesses in the color layer are preferably formed by openings in the carrier structure. The openings completely penetrate the carrier structure in the thickness direction. In other words, the openings are through-openings. This prevents the light emitted by the light sources from being weakened by the carrier structure. The recesses can be punched or plotted in the carrier structure, for example.

The base structure is advantageously designed to be flexible. In other words, the base structure is elastically deformable. In particular, the base structure can be bendable and/or rollable. This allows the lighting system to be used on curved surfaces. Furthermore, the lighting system can deform under external loads, for example in the case of wind. A mechanical load on the lighting system and on structures to which the lighting system is attached can also be reduced as a result. If the lighting system comprises a separate carrier structure having the color layer, the carrier structure is typically also flexible.

The base structure can be composed of a plurality of structural elements. As a result, the lighting system can be provided in a simple manner in a size and shape required for the relevant application. The structural elements can each be rectangular, in particular square. An edge length of the structural elements can be at least 40 cm, preferably at least 50 cm. The edge length of the structural elements can be at most 80 cm, preferably at most 70 cm. The edge length of the structural elements is particularly preferably approximately 60 cm.

The base structure can be rectangular. The base structure can have different dimensions, particularly if it is composed of a plurality of structural elements. An aspect ratio of the base structure can be 16:9. The lighting system is then particularly suitable for use in the manner of a screen. An aspect ratio of the base structure can be significantly greater than 16:9, in particular greater than 32:9. The lighting system is then particularly suitable for use on an architectural element, for example in order to support the optical effect of the architectural element.

The base structure can be undulating or round. These designs allow the lighting system to be better adapted to special applications. Furthermore, the base structure can be designed as a freeform surface.

It is possible, that the base structure or, if present, its structural elements can be cut to size. As a result, the shape and size of the lighting system can be flexibly adapted to the relevant intended application.

Adjacent structural elements of the base structure are preferably held at each other. This can simplify production and assembly of the lighting system. The structural elements are advantageously held together in a form-fitting manner. Alternatively or additionally, the structural elements can be held together in a force-fitting manner and/or in a materially bonded manner.

The structural elements can be held together in a lane. The base structure then consists of structural elements which follow one another in a longitudinal direction, of which adjacent structural elements are attached to one another in each case. The structural elements can each comprise holding elements which are opposite one another (in the longitudinal direction).

Alternatively, the structural elements can be held together in a two-dimensional manner. In other words, the base structure is then formed from a planar arrangement of structural elements. The structural elements can comprise holding elements in different directions. For example, rectangular structural elements can each comprise holding elements on their four lateral edges.

The light sources can be arranged (at least in some regions) in a regular grid, preferably in rows and columns which are orthogonal to one another. All of the light sources may be arranged in the regular grid. This simplifies actuation of the light sources for the reproduction of patterns or animations. Furthermore, a homogeneous light emission can be achieved in this way.

The light sources can be arranged (at least in some regions) in the form of a symbol. All of the light sources may form the symbol. In this way, for example, a character or a logo of a company to be advertised can be reproduced and can be highlighted by switching on the light sources.

All of the light sources may be designed to emit light of the same color. In other words, all of the light sources always emit light of the same color. As a result, the lighting system can be provided in a particularly cost-effective manner. Furthermore, this can simplify actuation of the light sources for reproducing animations or patterns. The light sources can be designed to emit white light. The light sources are preferably designed to emit white light with a changeable color temperature, for example as dual-white light sources, in particular dual-white LEDs.

Alternatively, it can be provided that the light sources are designed to emit light of different colors. This allows animations or patterns to be reproduced using different colors. The light sources are preferably in the form of RGB LEDs. The RGB LEDs can be RGBW LEDs or particularly preferably RGBWW LEDs. A color rendering index of the lighting system can be improved by LEDs for emitting light with a white component (in the case of RGBW LEDs), in particular different color temperatures (in the case of RGBWW LEDs). Alternatively, differently colored light sources can be arranged on the base structure in an alternating manner.

The lighting system preferably comprises a controller for actuating all of the light sources in a synchronized manner. The controller makes it possible to switch the light sources on and off separately or, advantageously, to vary the brightness of the light emitted in each case. If the light sources are designed to emit light of different colors, the controller also makes it possible to control the color rendering of the light sources. In particular, the controller can make it possible to control all light sources in a chronological sequence in order to reproduce the animations. The controller can make it possible to reproduce image or video files by means of the lighting system.

The lighting system can comprise a transparent cover structure. In particular, the cover structure can protect the light sources and the color layer from damage. The cover structure is preferably arranged at a distance from the base structure. The cover structure is advantageously clear. The cover structure then does not change the color impression of the color layer or of the light emitted by the light sources. Alternatively, the cover structure can be matt. This can contribute to a more homogeneous appearance of the lighting system, particularly when the light sources are switched on. The cover structure can be made of acrylic glass. The cover structure can, in particular in some regions, be colored, for example printed in color. A distance between the cover structure and the base structure can be at least 1 mm, preferably at least 2 mm, particularly preferably at least 5 mm. The distance between the cover structure and the base structure can be at most 10 cm, preferably at most 7 cm, particularly preferably at most 5 cm.

The lighting system can comprise a holding structure to which the base structure is attached. This can simplify the handling and mounting of the lighting system. Furthermore, the holding structure can protect the base structure from damage. The lighting system can be attached to buildings, for example, by means of the holding structure. The base structure can be non-detachably attached to the holding structure. The holding structure and the base structure can in particular be glued to one another. Alternatively, the base structure can be detachably attached to the holding structure. The base structure can in particular be attached to the holding structure by means of a hook-and-loop connection. The holding structure can be a tarpaulin, for example a PVC tarpaulin.

Further features and advantages of the invention can be found in the description and the drawings. Likewise, the aforementioned features and those which are to be explained below can each be used individually or as a plurality in expedient combinations of any kind. The embodiments shown and described are not to be understood as an exhaustive enumeration, but rather have exemplary character for the description of the invention.

### BRIEF DESCRIPTION OF THE DRAWINGS

The invention is shown in the drawings and is explained in more detail using embodiments. In the drawings:

FIG. 1 shows a lighting system according to the invention, comprising a plurality of light sources which are arranged on a base structure and are covered by a carrier structure having a color layer at a distance from the base structure, a recess being provided in the color layer for each of the light sources, in a schematic sectional view;

FIG. 2 shows a lighting system according to the invention, comprising a plurality of light sources which are each arranged in recesses of a carrier structure arranged directly on the base structure, in a schematic sectional view;

FIG. 3 shows a lighting system according to the invention, comprising a base structure which is composed of a plurality of structural elements and on which a plurality of light sources is arranged, with a color layer being applied directly to the structural elements of the base structure, in a schematic plan view.

### DETAILED DESCRIPTION OF THE PREFERRED EMBODIMENTS

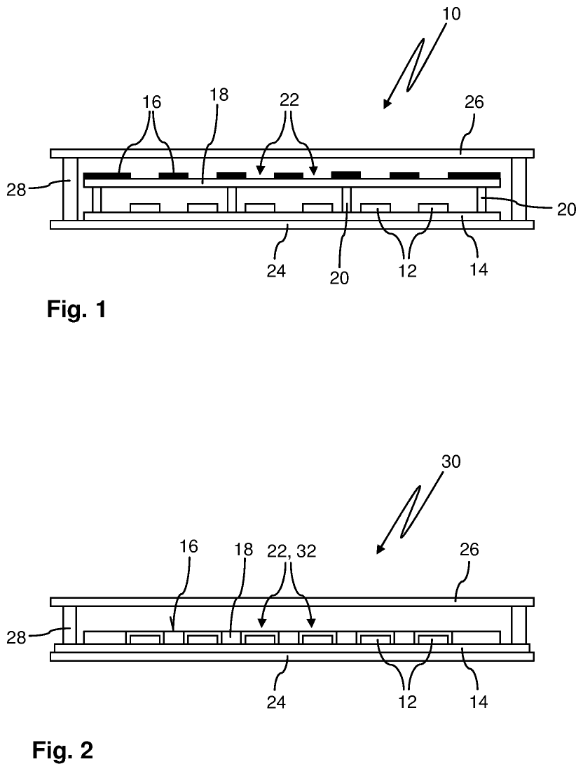

FIG. 1 is a basic sketch of a lighting system 10. The lighting system 10 is used to display animations for advertising purposes.

The lighting system 10 comprises a plurality of light sources 12. The light sources 12 can be designed as light-emitting diodes. In this embodiment, the light sources 12 are designed as RGB LEDs, for example. The light sources 12 are held on a base structure 14. The base structure 14 can be a flexible plastics film. The light sources 12 can be glued to the base structure 14. Alternatively, the light sources 12 can be embedded in the base structure 14. Lines (not shown in greater detail) for supplying the light sources 12 with electrical energy can be arranged on the base structure 14, in particular embedded in the base structure 14.

The lighting system 10 also comprises a color layer 16. The color layer 16 is applied to a carrier structure 18. The color layer 16 is printed onto the carrier structure 18 in this case. The carrier structure 18 can be a transparent plastics film. The carrier structure 18 is also flexible in this case. The carrier structure 18 having the color layer 16 can be arranged on the base structure 14 having the light sources 12 in such a way that a distance is established between the color layer 16 and the light sources 12. In this embodiment, the carrier structure 18 and the base structure 14 are glued to one another via spacer elements 20.

The color layer 16 comprises a recess 22 for each of the light sources 12. The recesses 22 are in this embodiment formed as interruptions in the colored printing on the carrier structure 18. An extension of the recesses 22 can substantially be as large as the extension of the light sources 12. Typically, the recesses 22 are at least as large as the light sources 12, but at most twice as large as the light sources 12.

Instead of the spaced arrangement of carrier structure 18 and base structure 14, the carrier structure 18 can abut the base structure 14 and the light sources 12 (not shown in greater detail). The recesses 22 in the color layer 16 are arranged above the light sources. In this case, the carrier structure 18 could be glued directly to the base structure 14.

The lighting system 10 can also comprise a holding structure 24. The holding structure 24 can be designed as a flexible plastics tarpaulin. The base structure 14 can be detachably held on the holding structure 24. In this embodiment, the base structure 14 and the holding structure 24 are connected to one another via hook-and-loop elements which are not shown in greater detail.

Furthermore, the lighting system 10 can comprise a transparent cover structure 26. The cover structure 26 is in this embodiment designed as a clear sheet, for example made of acrylic glass. The cover structure 26 can be attached to the holding structure 24 via fastening elements 28.

FIG. 2 is a basic sketch of a further lighting system 30. The lighting system 30 from FIG. 2, like the lighting system 10 from FIG. 1, is used to display animations for advertising purposes. The lighting systems 10 and 30 are constructed in a similar manner. The differences are primarily described below. Reference is also made to the above description.

The lighting system 30 comprises a plurality of light sources 12. The light sources 12 can be designed as light-emitting diodes. In this embodiment, the light sources 12 are designed as differently colored LEDs, for example. The light sources 12 are held on a base structure 14. A cover structure 26 can be attached to the base structure 14 via fastening elements 28.

The lighting system 10 also comprises a color layer 16. The color layer 16 is applied to a carrier structure 18. In this embodiment, the carrier structure 18 is colored in its entirety, so that the top side thereof that faces away from the base structure 14 forms the color layer 16. The carrier structure 18 can be a colored polystyrene panel, for example. The carrier structure 18 having the color layer 16 and the base structure 14 having the light sources 12 are directly glued to one another in this embodiment.

The color layer 16 comprises a recess 22 for each of the light sources 12. The recesses 22 are in this embodiment formed as openings 32 which completely penetrate the carrier structure 18 in the thickness direction. The light sources 12 are each arranged in one of the openings 32. For this purpose, the extension of the openings 32 is slightly larger, for example 10% to 20%, than the extension of the light sources 12.

Contrary to the illustration in FIGS. 1 and 2, the light sources 12 can be recessed in the base structure 14. The light sources 12 can in this case end flush with the base structure 14 on the upper side.

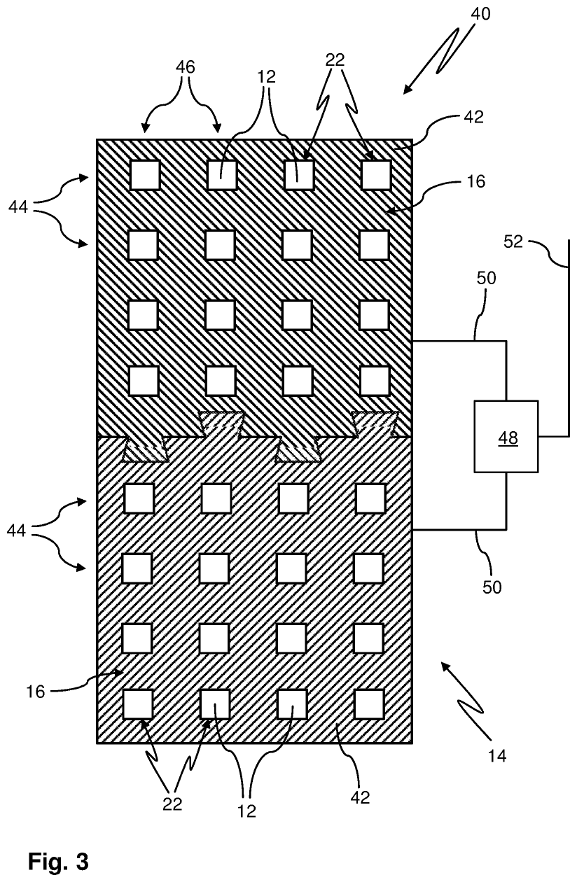

FIG. 3 is a basic sketch of a further lighting system 40. The lighting system 40 of FIG. 3, like the lighting systems 10 and 30 of FIG. 1 and FIG. 2, respectively, is used to display animations for advertising purposes.

The lighting system 30 comprises a plurality of light sources 12. The light sources 12 can be designed as light-emitting diodes. In this embodiment, the light sources 12 are designed as LEDs of the same color, e.g. white LEDs, for example. The light sources 12 are held on a base structure 14. The base structure 14 can be a flexible plastics film. The light sources 12 can be glued to the base structure 14. Alternatively, the light sources 12 can be embedded in the base structure 14. Lines (not shown in greater detail) for supplying the light sources 12 with electrical energy can be arranged on the base structure 14, in particular embedded in the base structure 14.

The lighting system 10 also comprises a color layer 16. The color layer 16 is applied directly to the base structure 14 in this embodiment. The base structure 14 can be coated in color, for example. The color layer 16 comprises a recess 22 for each of the light sources 12. An extension of the recesses 22 can substantially be as large as the extension of the light sources 12. The color layer 16 in this embodiment covers the entire upper region of the base structure 14 that is not occupied by the light sources 12.

The base structure 14 of the lighting system 40 is composed of a plurality of structural elements 42. Two structural elements 42 are shown here by way of example. The lighting system 40 is typically constructed with more than two structural elements 42. The structural elements 42 can be held directly against one another. Holding projections and holding openings can be formed on the edges of the structural elements 42 (only shown here at the common boundary of the two structural elements 42). The structural elements 42 can be connected to one another in a form-fitting manner by the holding projections of one structural element 42 engaging in the holding openings of the other structural element 42.

The base structures 14 of the lighting systems 10 and 30 of FIG. 1 and FIG. 2, respectively, can also be composed of a plurality of structural elements 42 (not shown in greater detail in said figures). The carrier structures 18 are then correspondingly composed of a plurality of carrier elements. Like the structural elements, the carrier elements can be designed for attachment to one another, in particular in a form-fitting manner.

The lighting system 40 can comprise a holding structure 24, as described above with respect to the lighting systems 10 and 30. Even if the lighting systems 10, 30 or 40 comprise a plurality of structural elements 42 and optionally carrier elements, only a single holding structure 24 is typically provided, to which all of the structural elements 42 are then attached.

A cover structure 26 as described above can also be provided in the lighting system 40. If a cover structure 26 is provided in a lighting system 10, 30 or 40 having a plurality of structural elements 42 and optionally carrier elements, said cover structure is typically formed in one piece. In other words, the one cover structure 26 can cover all of the structural elements 42 and, if provided, carrier elements.

In FIG. 3, it can be seen that the light sources 12 are arranged in a regular grid of a plurality of rows 44 and columns 46. The rows 44 and the columns 46 in this embodiment extend orthogonally to one another. It should be noted that adjacent structural elements 42 are typically connected in such a way that the same distance between the rows 44 or columns 46 that is established within one of the structural elements 42 is also established across the boundary of the structural elements 42. In the case of the lighting systems 10 and 30 (cf. FIGS. 1 and 2, respectively), the light sources 12 can also be arranged in a regular grid of rows 45 and columns 46 which are orthogonal to one another.

FIG. 3 also shows a controller 48 of the lighting system 40. Such a controller 48 can also be provided in the lighting systems 10 (cf. FIG. 1) and 30 (cf. FIG. 2); however, the controller 48 is not shown in FIGS. 1 and 2. The controller 48 is used to actuate all of the light sources 12 of the lighting system 40 in a synchronized manner. The controller 48 can be designed to switch the light sources 12 on or off independently of one another at short time intervals, for example with a repetition rate of at least 30 Hz, in particular 60 Hz, or preferably to dim said light sources and, if necessary, to select the light color emitted by the light sources 12. The lighting system 40 can reproduce animations by actuating all of the light sources 12 in chronological succession and in each case synchronously.

The controller 48 can be connected to the base structure 14 or its structural elements 42 via one or more control lines 50. In order to supply energy to the lighting system 40, a connection cable 52 can be provided on the controller.

Viewing all of the drawings in combination, the invention relates to a lighting system having a color layer 16 which comprises a plurality of recesses 22 which are each assigned a separate light source 12. Light emitted by the light sources 12 can exit through the recesses 22. Animated representations can be reproduced by actuating the light sources 12 in a chronological sequence. When the light sources 12 are switched off, the color impression of the color layer 16 can be seen. The color layer 16 can comprise different colors and in particular can be provided with a pattern and/or characters. The lighting system is preferably composed of a plurality of elements in the manner of a puzzle, in order, for example, to cover the entire surface of an advertising element having a complex shape.

### LIST OF REFERENCE SIGNS

lighting system 10, 30, 40
light sources 12
base structure 14
color layer 16
carrier structure 18
spacer elements 20
recess 22
holding structure 24
cover structure 26
fastening elements 28
openings 32
structural elements 42
rows 44
columns 46
controller 48
control lines 50
connection cable 52

What is claimed is:

1. A lighting system for displaying animations, comprising:
a plurality of light sources;
a base structure on which the light sources are held;
a color layer which is arranged on the base structure and which comprises a recess for each of the light sources; and
a controller configured for actuating the light sources in a synchronized manner in a chronological sequence in order to reproduce the animations.

2. The lighting system according to claim 1, wherein the color layer is applied directly to the base structure.

3. The lighting system according to claim 1, wherein the color layer is applied to a carrier structure.

4. The lighting system according to claim 3, wherein the carrier structure and the base structure are glued directly to one another.

5. The lighting system according to claim 3, wherein the carrier structure is arranged at a distance from the base structure.

6. The lighting system according to claim 3, wherein the recesses in the color layer are formed by openings in the carrier structure.

7. The lighting system according to claim 1, wherein the base structure is flexible.

8. The lighting system according to claim 1, wherein the base structure is composed of a plurality of structural elements.

9. The lighting system according to claim 8, wherein adjacent structural elements of the base structure are held at each other.

10. The lighting system according to claim 1, wherein the light sources are arranged in a regular grid, being in rows and columns which are orthogonal to one another.

11. The lighting system according to claim 1, wherein the light sources are arranged in the form of a symbol.

12. The lighting system according to claim 1, wherein all light sources are designed to emit light of the same color.

13. The lighting system according to claim 1, wherein the light sources are designed to emit light of different colors.

14. The lighting system according to claim 1, further comprising a transparent cover structure.

15. The lighting system according to claim 14, wherein the cover structure is arranged at a distance from the base structure.

16. The lighting system according to claim 1, further comprising a holding structure to which the base structure is attached.

17. The lighting system according to claim 1, wherein the plurality of light sources are light-emitting diodes

18. The lighting system according to claim 1, wherein all light sources are designed to emit light of the same color being white light.

19. The lighting system according to claim 1, wherein the light sources are designed to emit light of different colors being RGB LEDs.
